(19) United States
(12) Patent Application Publication
(10) Pub. No.: US 2025/0233575 A1
(43) Pub. Date: Jul. 17, 2025

(54) SURFACE ACOUSTIC WAVE STRUCTURES WITH EMBEDDED ACOUSTIC REFLECTORS

(71) Applicant: Qorvo US, Inc., Greensboro, NC (US)

(72) Inventors: Christian Huck, Munich (DE); Casey Kirkpatrick, Jamestown, NC (US); Jason Patrick Henning, Pittsboro, NC (US)

(21) Appl. No.: 18/989,901

(22) Filed: Dec. 20, 2024

Related U.S. Application Data
(60) Provisional application No. 63/621,737, filed on Jan. 17, 2024.

(51) Int. Cl. H03H 9/02; H03H 9/10; H03H 9/145; H03H 9/25

(52) U.S. Cl. CPC H03H 9/02661; H03H 9/02952; H03H 9/1092; H03H 9/145; H03H 9/25

(57) ABSTRACT

A surface acoustic wave (SAW) structure is provided. The SAW structure includes an interdigital transducer (IDT) over a first surface of a piezoelectric structure. The IDT includes a first electrode finger and a second electrode finger arranged in parallel along a first direction and at least partially overlapped with each other. The SAW structure also includes a first embedded acoustic reflector in the piezoelectric structure on one side of the IDT along a second direction, and a second embedded acoustic reflector in the piezoelectric structure on another side of the IDT along the second direction. A first surface of each of the first embedded acoustic reflector and the second embedded acoustic reflector is coplanar with the first surface of the piezoelectric structure. A second surface of each of the first embedded acoustic reflector and the second embedded acoustic reflector is located between the first surface and a second surface of the piezoelectric structure.

### CROSS REFERENCE

This application claims priority to U.S. Provisional Patent Application No. 63/621,737 filed Jan. 17, 2024, which is incorporated by reference herein in its entirety.

### FIELD OF THE INVENTION

This disclosure relates to surface acoustic wave (SAW) structures. In particular, this disclosure relates to SAW structures with embedded acoustic reflectors.

### BACKGROUND

Acoustic resonators are used in high-frequency communication applications such as 3rd Generation (3G), 4th Generation (4G), and 5th Generation (5G) wireless devices. Continuous advancement in mobile devices standards from one generation to the next requires integration of more filter bands for wireless communications. These filter bands can be deployed individually or in multiplexing applications via carrier aggregation. Besides the increased resonator counts for wireless communications, multiple other functions, which also keep increasing year over year, are integrated into modern mobile devices. Due to the limited real estate inside mobile devices with decent form factors, this requires continuous shrinking of solution sizes for each of these technologies to enable continuation of this evolution.

Surface Acoustic Wave (SAW) resonators using Temperature Compensated SAW (TC-SAW) or thin-film SAW technologies using layered substrates are widely used for low-band (LB) and mid-band (MB) filtering applications. As resonator counts in mobile devices increase, reducing the size of SAW resonator dies enables module shrink and additional band placements within the same footprint. A primary driver of die size for SAW resonators is the acoustic area which is defined by the deployed acoustic technology to realize a specific filtering performance. Decreasing acoustic area of SAW technologies will therefore enable module shrink and wafer cost savings.

To meet filtering requirements in mobile devices with limited space, there is a need to reduce the size of SAW resonators.

### SUMMARY

Aspects of the invention provide a surface acoustic wave (SAW) structure. The SAW structure includes an interdigital transducer (IDT) over a first surface of a piezoelectric structure. The IDT includes a first electrode finger and a second electrode finger arranged in parallel along a first direction and at least partially overlapped with each other. The SAW structure also includes a first embedded acoustic reflector in the piezoelectric structure on one side of the IDT along a second direction different from the first direction; and a second embedded acoustic reflector in the piezoelectric structure on another side of the IDT along the second direction. A first surface of each of the first embedded acoustic reflector and the second embedded acoustic reflector is coplanar with the first surface of the piezoelectric structure. A second surface of each of the first embedded acoustic reflector and the second embedded acoustic reflector is located between the first surface and a second surface of the piezoelectric structure.

In some embodiments, the first embedded acoustic reflector and the second embedded acoustic reflector each comprises an airgap.

In some embodiments, a first distance between each of the first embedded acoustic reflector and the second embedded acoustic reflector, and a closest one of the first electrode finger and the second electrode finger (e.g., last electrode finger) is between about 02 and about 152, 2 being the wavelength of the acoustic wave propagating in the IDT. In some embodiments, a second distance between the first surface and the second surface of each of the first embedded acoustic reflector and the second embedded acoustic reflector is between about 0.25 μm and about 52. In some embodiments, a first side surface of each of the first embedded acoustic reflector and the second embedded acoustic reflector closer to the IDT and a second side surface of each of the first embedded acoustic reflector and the second embedded acoustic reflector further from the IDT is at least 0.1 μm. In some embodiments, an angle between a side surface and the second surface is between about 80 degrees and about 135 degrees.

In some embodiments, the SAW structure further includes a first reflective grating over the piezoelectric structure and between the IDT and the first embedded acoustic reflector, and a second reflective grating over the piezoelectric structure and between the IDT and the second embedded acoustic reflector.

In some embodiments, the SAW structure further includes a second IDT over the piezoelectric structure apart from the IDT along the second direction, and a third embedded acoustic reflector in the piezoelectric structure between the second embedded acoustic reflector and the second IDT.

In some embodiments, a distance between the second embedded acoustic reflector and the third embedded acoustic reflector is between about 0.1 μm and about 2×15λ, λ being the wavelength of the acoustic wave propagating in the IDT.

In some embodiments, the SAW structure further includes a second IDT over the piezoelectric structure apart from the IDT along the second direction. The second IDT is immediately adjacent to the second embedded acoustic reflector.

In some embodiments, the SAW structure further includes a second IDT over the piezoelectric structure apart from the IDT along the second direction; a third embedded acoustic reflector in the piezoelectric structure and adjacent to the second embedded acoustic reflector; and a third reflective grating over the piezoelectric structure and between the second IDT and the third embedded acoustic reflector.

In some embodiments, a distance between the second embedded acoustic reflector and the third embedded acoustic reflector is between 0.1 μm and about 2×15λ, λ being the wavelength of the acoustic wave propagating in the IDT.

In some embodiments, the SAW structure further includes: a second IDT over the piezoelectric structure apart from the IDT along the second direction, and a third reflective grating over the piezoelectric structure and between the second IDT and the second embedded acoustic reflector.

In some embodiments, the piezoelectric structure includes a carrier substrate, a functional layer over the carrier substrate, and a piezoelectric layer over the functional layer.

In some embodiments, a distance between the first surface and the second surface of each of the first embedded acoustic reflector and the second embedded acoustic reflector is equal to or greater than a thickness of the piezoelectric layer.

In some embodiments, the second surface of each of the first embedded acoustic reflector and the second embedded acoustic reflector is in contact with the carrier substrate.

In some embodiments, the piezoelectric structure includes a bulk piezoelectric substrate.

In some embodiments, the SAW structure further includes: a first dummy electrode structure located between the IDT and the first embedded acoustic reflector in the second direction; and a second dummy electrode structure located between the IDT and the second embedded acoustic reflector in the second direction. A distance between the first embedded acoustic reflector and the first dummy electrode structure is zero such that an edge of the first dummy electrode structure aligns with a side surface of the first embedded acoustic reflector. A distance between the second embedded acoustic reflector and the second dummy electrode structure is zero such that an edge of the second dummy electrode structure aligns with a side surface of the second embedded acoustic reflector.

In some embodiments, along the second direction, a dimension of the first dummy electrode structure or the second dummy electrode structure is equal to, less than, or greater than a dimension of the first electrode finger or the second electrode finger.

In some embodiments, the SAW structure further includes: a first reflective grating located between the first dummy electrode structure and the IDT; and a second reflective grating located between the second dummy electrode structure and the IDT.

In some embodiments, the SAW structure further includes a packaging structure covering the IDT, the first embedded acoustic reflector, and the second embedded acoustic reflector. The packaging structure includes a first portion in contact with the piezoelectric structure and a second portion in contact with the first portion.

In some embodiments, the first portion of the packaging structure is located apart from the IDT, the first embedded acoustic reflector, and the second embedded acoustic reflector such that the second portion of the packaging structure is separated from the IDT, the first embedded acoustic reflector, and the second embedded acoustic reflector by another airgap.

In some embodiments, the first portion of the packaging structure is located apart from the IDT, and over the first embedded acoustic reflector and the second embedded acoustic reflector such that the second portion of the packaging structure is separated from the IDT by another airgap.

In some embodiments, the first portion of the packaging structure is located apart from the IDT, and partially filling the first embedded acoustic reflector and the second embedded acoustic reflector such that the second portion of the packaging structure is separated from the IDT, a rest of the first embedded acoustic reflector and the second embedded acoustic reflector by another airgap.

In some embodiments, the first portion of the packaging structure is located apart from the IDT, and fully filling the first embedded acoustic reflector and the second embedded acoustic reflector such that the second portion of the packaging structure is separated from the IDT by another airgap.

### BRIEF DESCRIPTION OF THE DRAWINGS

FIG. 1 illustrates a cross-sectional view of an existing SAW resonator with reflective gratings.

FIGS. 2-10 each illustrates a cross-sectional view of an exemplary SAW structure with embedded acoustic reflectors, according to some embodiments of the present disclosure.

FIGS. 11A-11D each illustrates a cross-sectional view of an exemplary packaged SAW structure with embedded acoustic reflectors, according to some embodiments of the present disclosure.

FIG. 12 illustrates a comparison in performance on a resonator level between a SAW with reflective gratings and an exemplary SAW with embedded acoustic reflectors, according to some embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein. Additionally, like reference numerals denote like features throughout specification and drawings.

Reference will now be made in greater detail to various embodiments of the subject matter of the present disclosure, some embodiments of which are illustrated in the accompanying drawings.

In an existing SAW resonator, reflective gratings (RG) are often used on both ends of an interdigital transducer (IDT), in which an acoustic wave, having a wavelength λ, propagates. The RGs confine the acoustic wave energy longitudinally and minimize acoustic leakage. However, the RGs can consume a lot of space in SAW resonators since they are typically multiple wavelengths (10λ or more) long. For example, in a die, the RGs can make up to, e.g., at least 18.3% of the total acoustic area and 6.6% of the total die area. Thus, a more space-efficient reflector alternative to the RGs is desired.

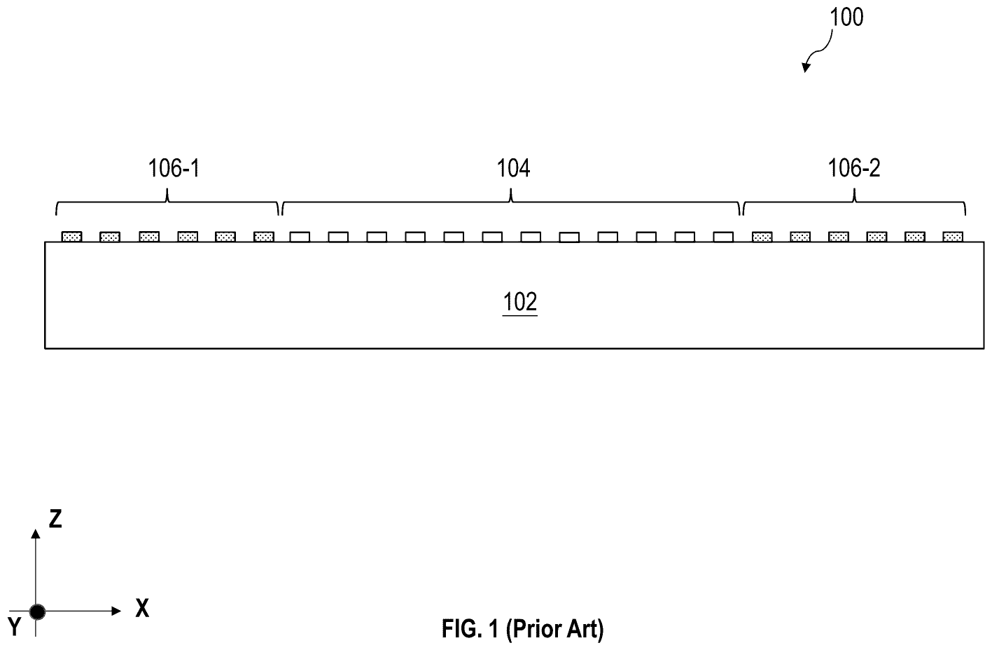

FIG. 1 shows a cross-sectional view of an existing SAW resonator 100. SAW resonator 100 includes an IDT 104 over a substrate 102, which includes a piezoelectric material. IDT 104 includes a plurality of electrode fingers arranged interweavingly on substrate 102. The electrode fingers may belong to two electrodes, with some being part of one of the electrodes, and the others being part of the other electrode. The electrode fingers may interact with the piezoelectric material such that electrodes may cause SAW excitation. In various embodiments, the electrodes (and/or the electrode fingers) may have other configurations such as split-fingers or multiple IDT's in a CRF topology. The specific configuration of the electrodes should not be limited to the embodiments of the present disclosure. An acoustic wave, with a wavelength λ, propagates in IDT 104 and substrate 102 in the x-direction. SAW resonator 100 also includes a first RG 106-1 on one side of IDT 104, and second RG 106-2 on the other side of IDT. First RG 106-1 and second RG 106-2 provide confinement of the acoustic wave in the x-direction. As mentioned, first RG 106-1 and second RG 106-2 can each have the size of at least 102 in the x-direction. The RGs can thus take an undesirably large area in SAW resonator 100 and the respective die.

Embodiments of the present disclosure provide SAW structures with novel embedded acoustic reflectors that are located in the supporting structure on which the IDT is located. The embedded acoustic reflectors have desirably high confinement of the acoustic wave, and take much less space than the RGs. An embedded acoustic reflector may include an opening or a groove, located on one side of an IDT. Along the x-direction, the embedded acoustic reflector has a much smaller dimension than RGs, but has comparable acoustic reflectivity/confinement. The embedded acoustic reflector may have a sufficient depth to provide desirably high acoustic reflectivity/confinement. The embedded acoustic reflector may be filled with a material that has a different acoustic impedance than that of the supporting structure. In some embodiments, the embedded acoustic reflector is filled with air such that the embedded acoustic reflector includes an airgap. In some embodiments, the embedded acoustic reflector is partially or fully filled with a packaging material. Because the packaging material can partially or fully fill the embedded acoustic reflector while encapsulating the IDT, the area required by the packaged SAW structure can be further reduced. Details are described below.

In this disclosure, the space-consuming conventional reflective gratings may be replaced with size-efficient embedded acoustic reflectors. The embedded acoustic reflectors may be grooves or canyons in the supporting structure on both sides of the IDT and serve as reflecting structures. In some embodiments, the embedded acoustic reflectors are combined with conventional reflector gratings to provide higher confinement or confinement of acoustic waves with various wavelengths. The embedded acoustic reflector can be realized much shorter compared to conventional reflective gratings. In some embodiments, the embedded acoustic reflectors can provide better performance while occupying smaller area. In some embodiments, an embedded acoustic reflector can be shared with longitudinally adjacent acoustic structures (resonators or coupled resonator filter's) such that only one embedded acoustic reflector is needed to replace two reflective gratings between them. In some embodiments, the embedded acoustic reflectors can be realized by self-aligning features in the electrode metal layer, e.g., IDT. In some embodiments, embedded acoustic reflectors can be combined with wafer level packaging (WLP), e.g., to further reduce packaging area.

In this disclosure, a reflective grating includes a periodic structure such as one or more parallel lines or grooves over/on a surface. An embedded acoustic reflector includes an opening or groove located partially or fully below a surface. For example, an embedded acoustic reflect may be located in a base/support structure such as a substrate.

The disclosure addresses the limitation of the current SAW technologies regarding minimum achievable filter die size. The proposed solution provides a significant die size shrink by introducing a new approach for energy confinement in SAW resonators. By changing the reflecting structure for longitudinal acoustic wave confinement, the required acoustic area can be reduced significantly. The novel SAW structure has been demonstrated by FEM simulations on a SAW technology where it is attractive regarding performance and size benefits, in some embodiments.

This disclosure discloses a novel reflector approach for longitudinal energy confinement of acoustic waves by introducing an embedded acoustic reflector, e.g., a so-called reflector canyon (RC), for SAW devices. The RC's are positioned on both sides of the IDT and act as reflecting structures for SAW replacing the conventional RG's. The geometry of each RC has the following degrees of freedom which are also indicated in the figures: 1) the distance between the respective IDT and the RC, 2) the width of the RC in longitudinal x-direction along the SAW main propagation direction, 3) the depth of the RC in z-direction into the substrate, 4) the angles of the RC defining its shape at the sidewalls (in some embodiments, the angles are different), and 5) the RC's on both sides and having the same geometry or individual geometries differing from each other.

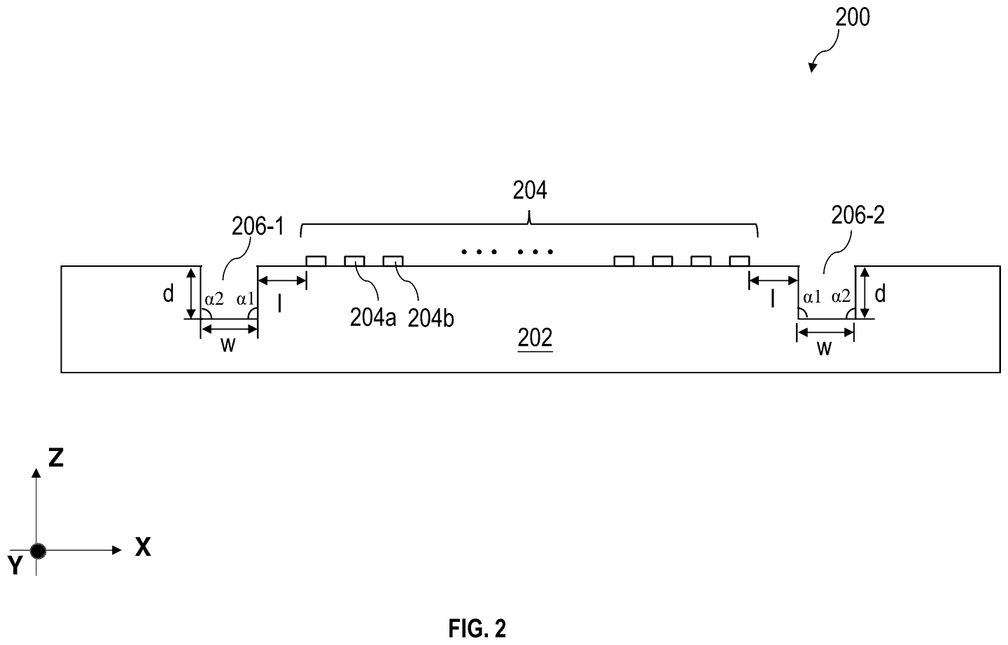

FIG. 2 illustrates a cross-sectional view of an exemplary SAW structure 200, according to embodiments of the present disclosure. SAW structure 200 may include a piezoelectric structure 202, an IDT 204 over piezoelectric structure 202, and one or more embedded acoustic reflectors 206-1 and 206-2 on one or both sides of IDT 204 along the x-direction. Piezoelectric structure 202 may include a piezoelectric material, which may include aluminum nitride (AlN), zinc oxide (ZnO), aluminum scandium nitride (AlScN), lithium tantalate (LT), lithium niobate (LN), and/or other suitable materials. In some embodiments, piezoelectric layer 102 includes LT and/or LN. In some embodiments, piezoelectric structure 202 includes a piezoelectric substrate, e.g., a bulk piezoelectric substrate that includes the one or more of the abovementioned piezoelectric materials, such that IDT 204 is in contact with the bulk piezoelectric substrate. In some embodiments, piezoelectric structure 202 includes a multi-layer structure, which includes a carrier substrate, one or more functional layers over the carrier substrate, and a piezoelectric layer over the functional layer(s). The piezoelectric layer may include one or more of the abovementioned piezoelectric materials. For case of illustration, SAW structure 200 includes a bulk piezoelectric substrate.

IDT 204 may be located on a first surface, e.g., the top surface, of piezoelectric structure 202. IDT 204 may include one or more first electrode fingers 204a and one or more second electrode fingers 204b extending in parallel in the y-direction. First electrode fingers 204a and second electrode fingers 204b may be arranged interweavingly such that each first electrode finger 204a is at least partially overlapped with an adjacent second electrode finger 204b, along the y-direction. First electrode fingers 204a and second electrode fingers 204b may include a suitable metal such as copper (Cu), tungsten (W), titanium (Ti), aluminum (Al), aluminum copper (AlCu), molybdenum (Mo), and/or platinum (Pt).

In some embodiments, SAW structure 200 includes a pair of embedded acoustic reflectors 206-1 and 206-2 located in piezoelectric structure 202 on both sides of IDT 204 in the x-direction. Embedded acoustic reflectors 206-1 and 206-2 may also be referred to as reflector canyons, reflector grooves, reflector airgaps, embedded reflectors, etc. Embedded acoustic reflectors 206-1 and 206-2 may each be located away from IDT 204, e.g., the edge of the closest electrode finger, by a distance 1 in the x-direction. In various embodiments, distance 1 ranges between about 0λ and about 15λ, λ being the wavelength of the acoustic wave propagating in IDT 204. Merely as an example, λ may be about 5.14 μm. A depth d of embedded acoustic reflectors 206-1 and 206-2, e.g., from a first surface (e.g., the top surface) to a second surface (e.g., the bottom surface) of embedded acoustic reflector 206-1/206-2, may range between about 0.10 μm and about 52 (e.g., between about 0.10 μm and about 26 μm). In some embodiments, depth d can be any suitable value (e.g., up to 200 μm, such as 50 μm, 75 μm, 100 μm, 120 μm, 180 μm, 200 μm, etc.) less than the thickness of the underlying piezoelectric structure 202. In some embodiments, as shown in FIG. 2, the first surface of embedded acoustic reflector 206-1/206-2 is coplanar with the first surface of piezoelectric structure 202. A width w of embedded acoustic reflector 206-1/206-2, e.g., between a first sidewall closer to IDT 204 and a second sidewall further from IDT 204, may have a minimum value of about 0.1 μm. For example, width w may range between about 0.1 μm and about 50 μm. An angle α1 between the first sidewall and the second surface of embedded acoustic reflector 206-1/206-2 may range between about 80 degrees and about 135 degrees, and an angle α2 between the second sidewall and the second surface of embedded acoustic reflector 206-1/206-2 may range between about 80 degrees and about 135 degrees. In some embodiments, α1 and α2 are each greater than or equal to 90 degrees.

It should be noted that, the quantities/values regarding the embedded acoustic reflectors in this disclosure are determined based on the optimized filter design for a given application. For example, the embedded acoustic reflectors are configured to maximize the confinement of the acoustic wave(s) in the IDT region. The wavelength(s) of the acoustic wave(s) propagating in the IDT(s) of the present disclosure may vary for different applications. In various embodiments, the values of 1, w, d, α1, and/or α2 may vary, depending on the specific application, and are thus not limited by the embodiments of the present disclosure. For example, the value of d may be sufficiently large to confine a desired acoustic wave for a specific technology. In various embodiments, the value of d may change in different SAW structures to provide confinement to acoustic waves of different wavelengths. In various embodiments, the values of 1, w, d, α1, and/or α2 in embedded acoustic reflector 206-1 may be the same as or different from those of embedded acoustic reflector 206-2.

Embedded acoustic reflectors 206-1 and 206-2 may be filled with a material that has an acoustic impedance sufficiently different from that of piezoelectric structure 202. The existence of this material, in contrast to air, may cause acoustic waves to attenuate. In some embodiments, embedded acoustic reflectors 206-1 and 206-2 are partially or fully filled with air. For example, embedded acoustic reflectors 206-1 and 206-2 may be airgaps, as shown in FIG. 2. In some embodiments, embedded acoustic reflectors 206-1 and 206-2 are partially or fully filled with other suitable materials, such as a packaging material, .e.g., epoxy (e.g., SU8, TMMF).

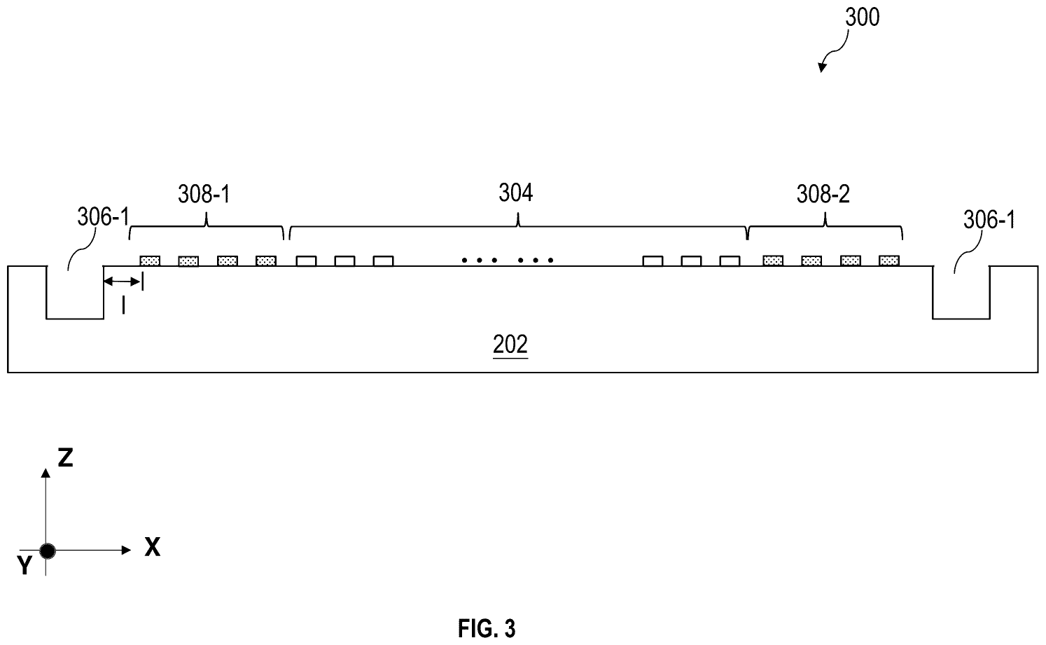

FIG. 3 illustrates another exemplary SAW structure 300, according to some embodiments. SAW structure 300 may include a piezoelectric structure 202, an IDT 304 over piezoelectric structure 202, and a pair of embedded acoustic reflectors 306-1 and 306-2 on each side of IDT 304 along the x-direction. IDT 304 and embedded acoustic reflectors 306-1 and 306-2 may be similar to their counter parts in SAW structure 200, and the detailed description is not repeated herein. Different from SAW structure 200, SAW structure 300 may include one or more reflective gratings between an embedded acoustic reflector and IDT 304. In some embodiments, SAW structure 300 includes one or more reflective gratings 308-1 between IDT 304 and embedded acoustic reflector 306-1, and includes one or more reflective gratings 308-2 between IDT 304 and embedded acoustic reflector 306-2. In some embodiments, reflective gratings 308-1 and 308-2 may include the same material as IDT 304 and be electrically connected to one of the electrodes of IDT 304 or to none of them being electrically floating. In some embodiments, the dimensions, shape, and pitch of a reflective grating is the same as an electrode finger. In some embodiments, as shown in FIG. 3, the distance 1 between embedded acoustic reflector 306-1/306-2 and the closest reflective grating 308-1/308-2 is greater than zero.

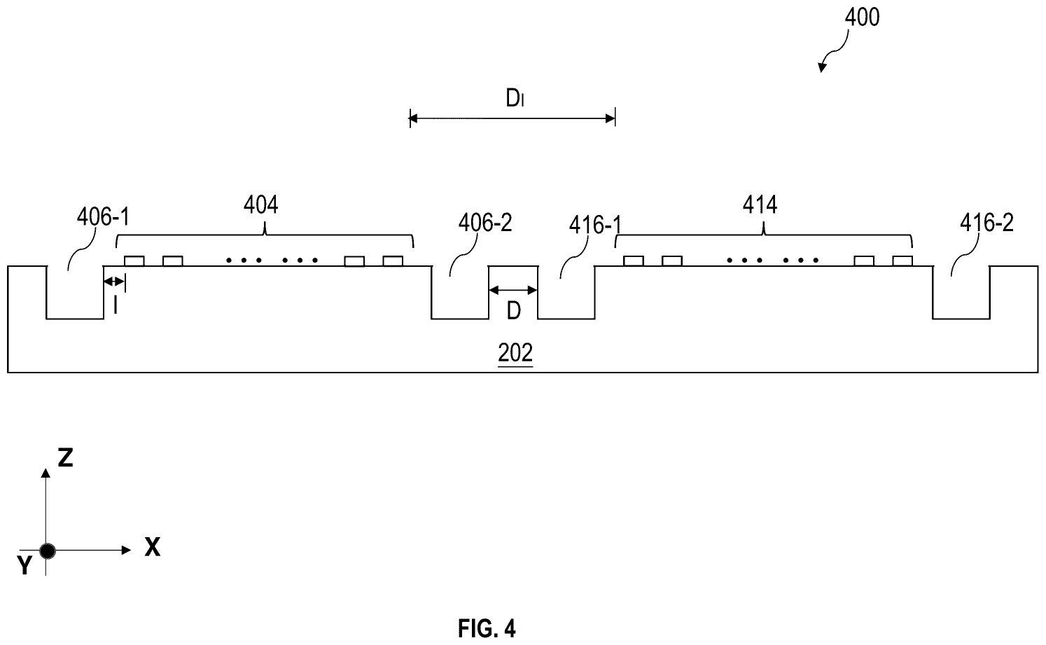

FIG. 4 illustrates another exemplary SAW structure 400, according to some embodiments. SAW structure 400 may include a piezoelectric structure 202, an IDT 404 over piezoelectric structure 202, and a pair of embedded acoustic reflectors 406-1 and 406-2 on each side of IDT 404 along the x-direction. IDT 404 and embedded acoustic reflectors 406-1 and 406-2 may be similar to their counter parts in SAW structure 200, and the detailed description is not repeated herein. Different from SAW structure 200, SAW structure 400 may include another IDT 414, and another pair of embedded acoustic reflectors 416-1 and 416-2 on each side of IDT 414. In some embodiments, IDT 414 is similar to IDT 404, and embedded acoustic reflectors 416-1 and 416-2 are similar to embedded acoustic reflectors 406-1 and 406-2, respectively. As shown in FIG. 4, IDT 414 and embedded acoustic reflectors 416-1 and 416-2 may be on one side of IDT 404 and embedded acoustic reflectors 406-1 and 406-2. In some embodiments, embedded acoustic reflector 406-2 is adjacent to embedded acoustic reflector 416-1, and a distance D between embedded acoustic reflector 406-2 and embedded acoustic reflector 416-1 (e.g., the distance between the closest sidewalls of embedded acoustic reflector 406-2 and embedded acoustic reflector 416-1) is greater than zero. In some embodiments, D has a minimum value of about 0.1 μm. In some embodiments, a distance D1 between IDT 404 and IDT 414 ranges from about 0.1 μm and about 15λ. In some embodiments, as shown in FIG. 4, the distance 1 between embedded acoustic reflector 406-1/406-2 and the closest electrode finger is greater than zero.

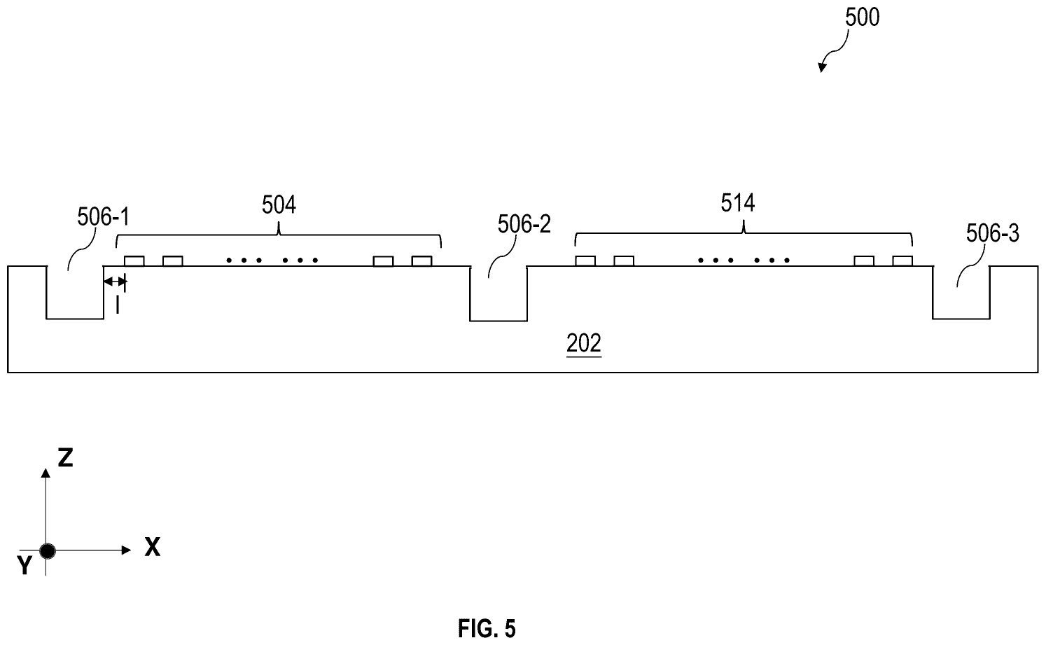

FIG. 5 illustrates another exemplary SAW structure 500, according to some embodiments. SAW structure 500 may include a piezoelectric structure 202, an IDT 504 over piezoelectric structure 202, and a pair of embedded acoustic reflectors 506-1 and 506-2 on each side of IDT 504 along the x-direction. Similar to SAW structure 400, SAW structure 500 may include another IDT 514 on one side of IDT 504. Different from SAW structure 400, SAW structure 500 may include a single embedded acoustic reflector 506-2 located between IDTs 504 and 514. SAW structure 500 may include another embedded acoustic reflector 506-3 on the other side of IDT 514, along the x-direction. Embedded acoustic reflectors 506-1 and 506-2 may provide confinement for acoustic waves propagating in IDT 504, and embedded acoustic reflectors 506-2 and 506-3 may provide confinement for acoustic waves propagating in IDT 514. In other words, IDTs 504 and 514 may share embedded acoustic reflector 506-2 for wave confinement. IDTs 504 and 514, and embedded acoustic reflectors 506-1, 506-2, and 506-3 may be similar to their counter parts in SAW structure 400, and the detailed description is not repeated herein. In some embodiments, as shown in FIG. 5, the distance 1 between embedded acoustic reflector 506-1/506-2/506-3 and the closest electrode finger is greater than zero.

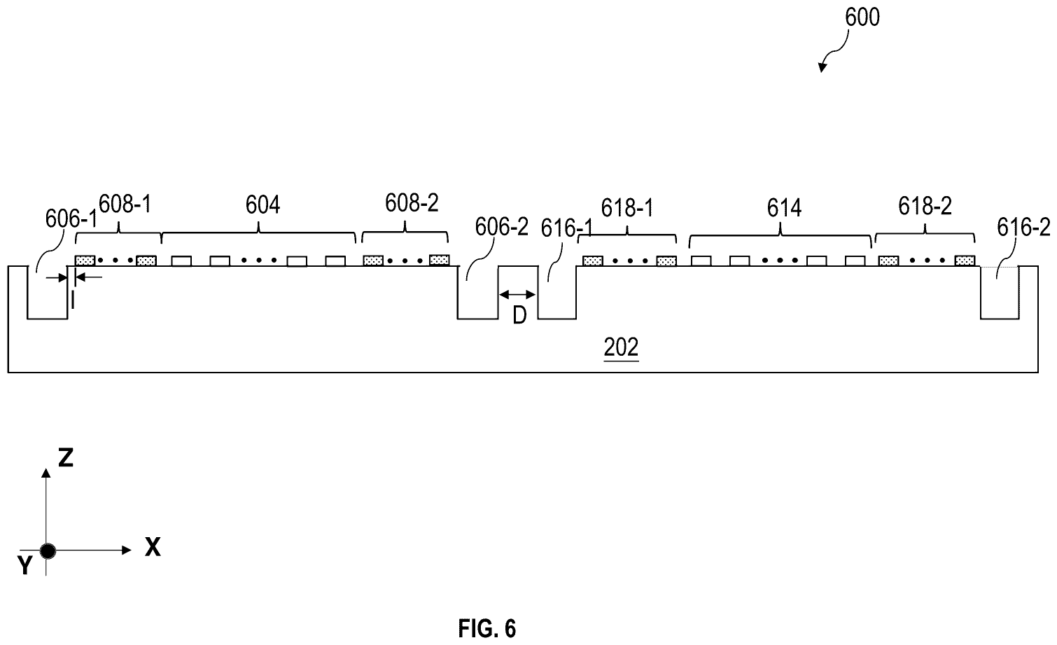

FIG. 6 illustrates another exemplary SAW structure 600, according to some embodiments. SAW structure 600 may include a piezoelectric structure 202. Similar to SAW structure 400, SAW structure 600 may include an IDT 604 and an IDT 614 over piezoelectric structure 202, a pair of embedded acoustic reflectors 606-1 and 606-2 on each side of IDT 604 along the x-direction, and a pair of embedded acoustic reflectors 616-1 and 616-2 on each side of IDT 614 along the x-direction. IDTs 604 and 614, and embedded acoustic reflectors 606-1, 606-2, 616-1, and 616-2 may be similar to their counter parts in SAW structure 400, and the detailed description is not repeated herein. In some embodiments, embedded acoustic reflector 606-2 is adjacent to embedded acoustic reflector 616-1, and a distance D between embedded acoustic reflector 606-2 and embedded acoustic reflector 616-1 (e.g., the distance between the closest sidewalls of embedded acoustic reflector 606-2 and embedded acoustic reflector 616-1) is at least 0.1 μm. Different from SAW structure 400, SAW structure 600 may include one or more reflective gratings between an IDT and an embedded acoustic reflector. As shown in FIG. 6, SAW structure 600 includes one or more reflective gratings 608-1 between IDT 604 and embedded acoustic reflector 606-1, one or more reflective gratings 608-2 between IDT 604 and embedded acoustic reflector 606-2, one or more reflective gratings 618-1 between IDT 614 and embedded acoustic reflector 616-1, and one or more reflective gratings 618-2 between IDT 614 and embedded acoustic reflector 616-2. In some embodiments, as shown in FIG. 4, the distance 1 between embedded acoustic reflector 606-1/606-2/616-1/616-2 and the closest reflective grating is greater than zero. In an embodiment, distance 1 of SAW structure 600 may be the same as or similar to distance 1 of SAW structure 400.

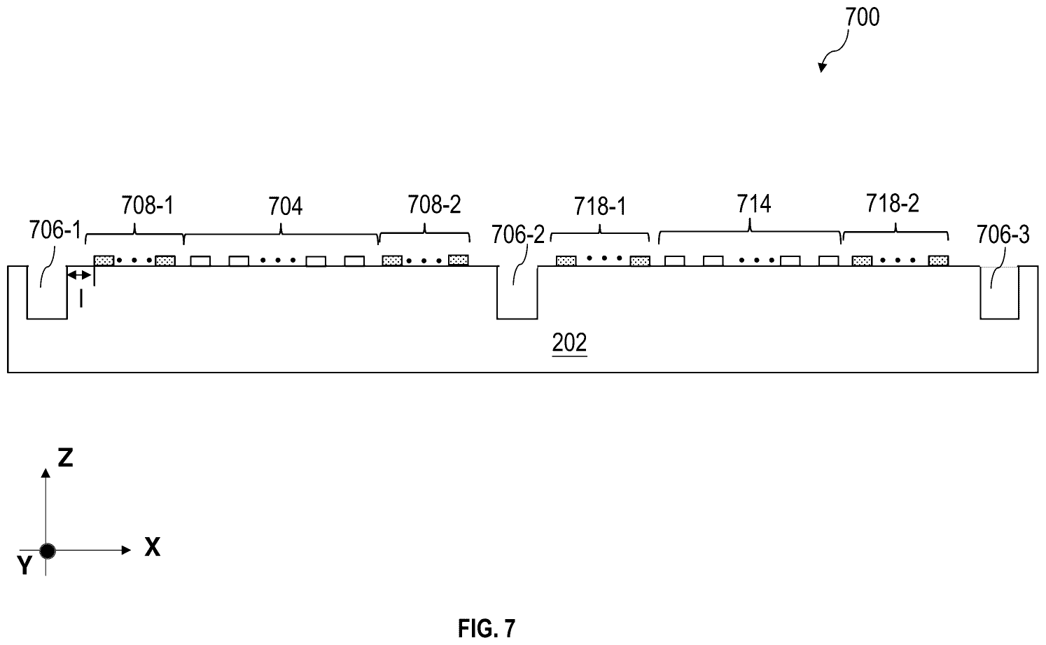

FIG. 7 illustrates another exemplary SAW structure 700, according to some embodiments. SAW structure 700 may include a piezoelectric structure 202. Similar to SAW structure 600, SAW structure 700 may include an IDT 704 and an IDT 714 over piezoelectric structure 202, and one or more reflective gratings between and an IDT and an embedded acoustic reflector. Different from SAW structure 600, SAW structure 700 may include a single embedded acoustic reflector between IDTs 704 and 714. As shown in FIG. 7, SAW structure 700 may include a pair of embedded acoustic reflectors 706-1 and 706-2 on each side of IDT 704 along the x-direction, and a pair of embedded acoustic reflectors 706-2 and 706-3 on each side of IDT 714 along the x-direction. In some embodiments, embedded acoustic reflector 706-2 is located between IDTs 704 and 714, e.g., being shared by IDTs 704 and 714, to provide confinement in acoustic waves propagating in both IDTs 704 and 714. Similar to SAW structure 600, SAW structure 700 may include one or more reflective gratings 708-1 between IDT 704 and embedded acoustic reflector 706-1, one or more reflective gratings 708-2 between IDT 704 and embedded acoustic reflector 706-2, one or more reflective gratings 718-1 between IDT 714 and embedded acoustic reflector 706-2, and one or more reflective gratings 718-2 between IDT 714 and embedded acoustic reflector 706-3. In some embodiments, IDTs 704 and 714, embedded acoustic reflectors 706-1, 706-2, and 706-3, and reflective gratings 708-1, 708-2, 718-1, and 718-2 may be similar to their counter parts in SAW structure 600, and the detailed description is not repeated herein. In some embodiments, as shown in FIG. 7, the distance 1 between embedded acoustic reflector 706-1/706-2/716-3 and the closest reflective grating is greater than zero. In an embodiment, distance 1 of SAW structure 700 may be the same as or similar to distance 1 of SAW structure 400.

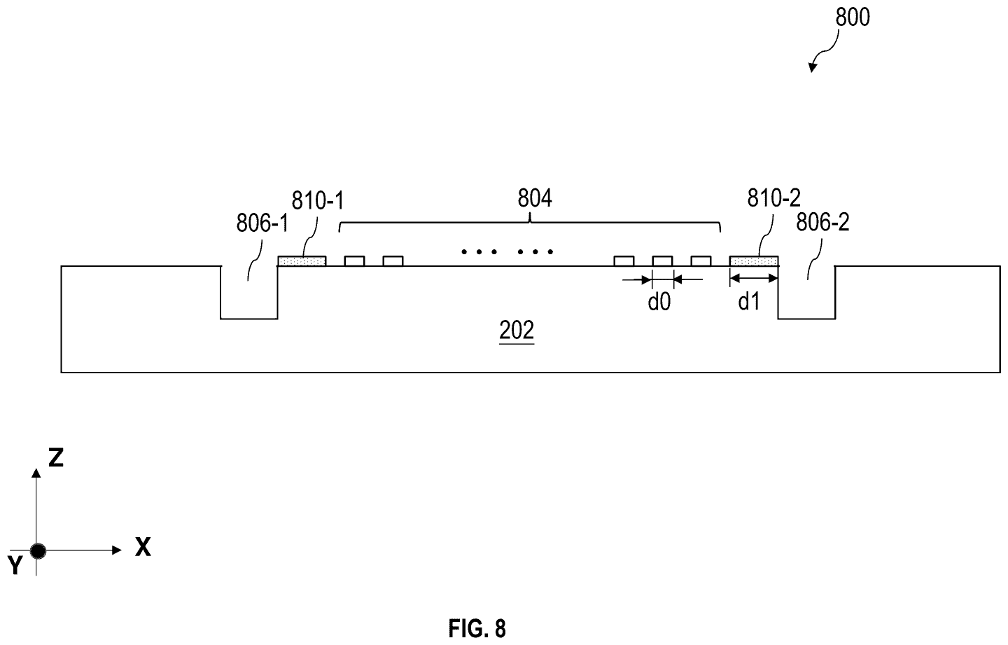

FIG. 8 illustrates another exemplary SAW structure 800, according to some embodiments. Similar to SAW structure 200, SAW structure 800 may include a piezoelectric structure 202, an IDT 804 over piezoelectric structure 202, and a pair of embedded acoustic reflectors 806-1 and 806-2 on both sides of IDT 804 in the x-direction. In some embodiments, IDT 804 and embedded acoustic reflectors 806-1 and 806-2 may be similar to their counter parts in SAW structure 200, and the detailed description is not repeated herein. Different from SAW structure 200, SAW structure 800 may include one or more, e.g., a pair of, dummy electrode structures 810-1 and 810-2 on both sides of IDT 804. Dummy electrode structures 810-1 and 810-2 may have the same material as the electrode fingers of IDT, but might be larger in size in the x-direction. Dummy electrode structures 810-1 and 810-2 may not be electrically activated, e.g., having no electrical contact with any of the electrodes of the IDT 804. In some embodiments, dummy electrode structures 810-1 and 810-2 may be used as a mask for self-alignment in the formation, e.g., etching, of embedded acoustic reflectors 806-1 and 806-2. For example, dummy electrode structures 810-1 and 810-2 may be formed in the same patterning process to form the electrode fingers of IDT 804, except that dummy electrode structures 810-1 and 810-2 do not need to be patterned to be as the same small dimension as the electrode fingers. Dummy electrode structures 810-1 and 810-2 may then be used as a mask to etch an opening in piezoelectric structure 202 to form embedded acoustic reflectors 806-1 and 806-2.

As shown in FIG. 8, dummy electrode structure 810-1 may be located between IDT 804 and embedded acoustic reflector 806-1, and dummy electrode structure 810-2 may be located between IDT 804 and embedded acoustic reflector 806-2. The distance, in the x-direction, between dummy electrode structure 810-1/810-2 and the respective embedded acoustic reflector is zero. In some embodiments, as shown in FIG. 8, along the z-direction, an outer side surface of dummy electrode structure 810-1 may align with the first side wall of embedded acoustic reflector 806-1, and an outer side surface of dummy electrode structure 810-2 may align with the first side wall of embedded acoustic reflector 806-2. In the x-direction, dummy electrode structure 810-1 may have a dimension dl, and an electrode finger may have a dimension do. In various embodiments, dl may be equal to, less than, or greater than do.

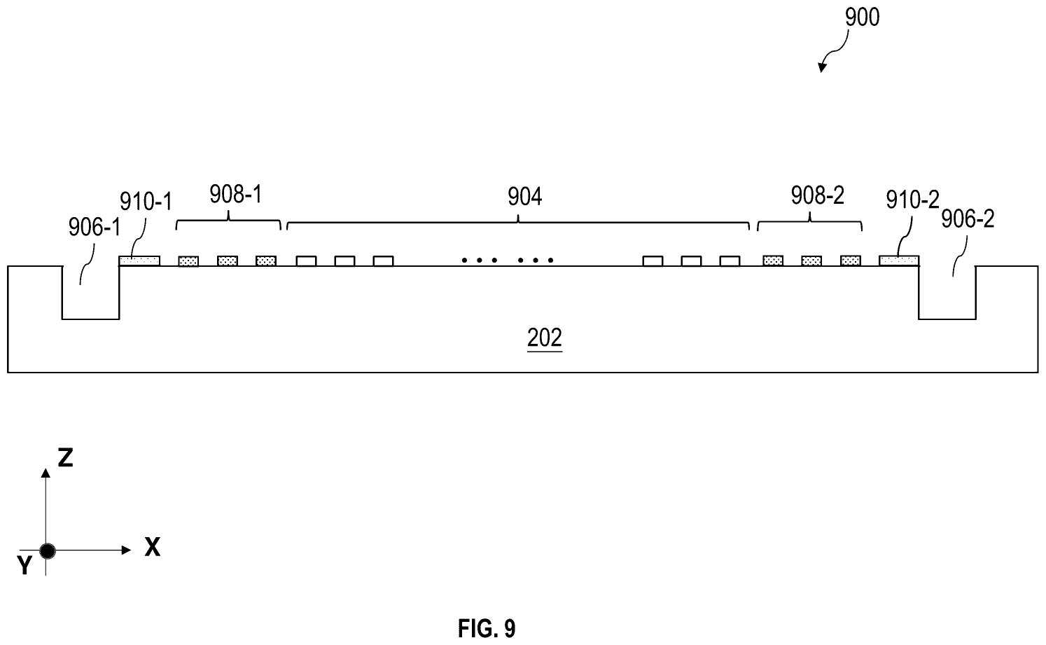

FIG. 9 illustrates another exemplary SAW structure 900, according to some embodiments. Similar to SAW structure 800, SAW structure 900 may include a piezoelectric structure 202, an IDT 904 over piezoelectric structure 202, a pair of embedded acoustic reflectors 906-1 and 906-2 on both sides of IDT 904 in the x-direction, and a pair of dummy electrode structures 910-1 and 910-2 each located immediately adjacent to the respective embedded acoustic reflector. Similar to SAW structure 900, the distance, in the x-direction, between dummy electrode structure 910-1/910-2 and the respective embedded acoustic reflector is zero. In some embodiments, as shown in FIG. 9, along the z-direction, an outer side surface of dummy electrode structure 910-1/910-2 may align with the first side wall of the respective embedded acoustic reflector. Different from SAW structure 800, over piezoelectric structure 202, SAW structure 900 may include one or more reflective grating 908-1 between dummy electrode structure 910-1 and IDT 904, and one or more reflective grating 908-2 between dummy electrode structure 910-2 and IDT 904. In some embodiments, dummy electrode structures 910-1 and 910-2 are similar to their counterparts 810-1 and 810-2. In some embodiments, IDT 904, embedded acoustic reflectors 906-1 and 906-2, and reflective gratings 908-1 and 908-2 may be similar to their counter parts in SAW structure 800. The detailed description of these structures is not repeated herein.

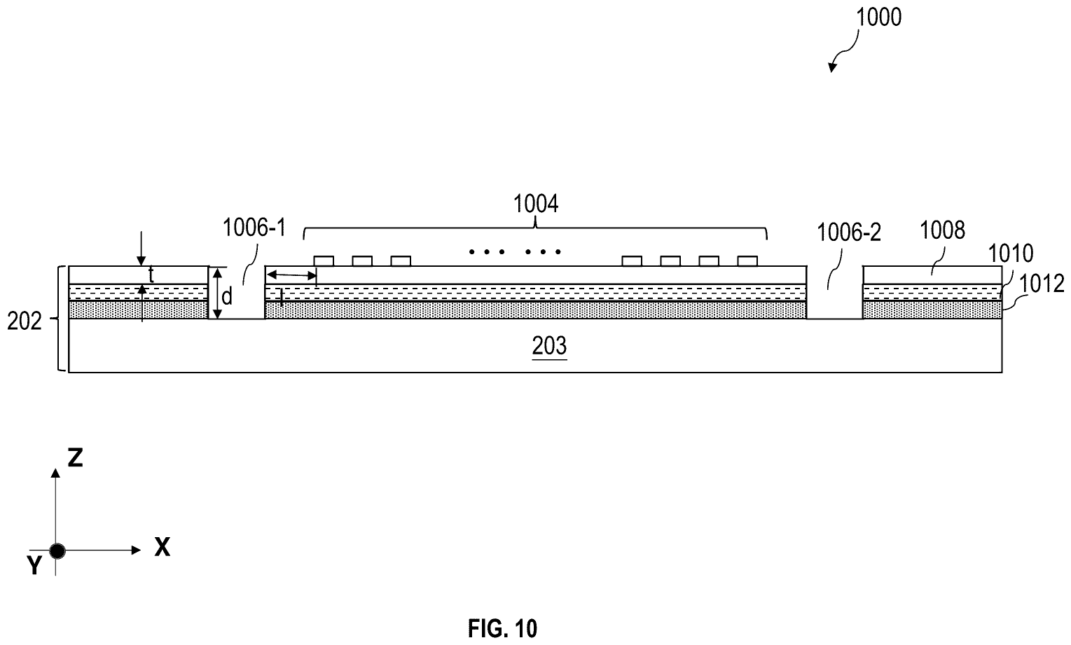

FIG. 10 illustrates another exemplary SAW structure 1000, according to some embodiments. SAW structure 1000 may include a piezoelectric structure 202, an IDT 1004 over piezoelectric structure 202, and a pair of embedded acoustic reflectors 1006-1 and 1006-2 on both sides of IDT 1004 in the x-direction. In some embodiments, IDT 1004 may be similar to IDT 204 in SAW structure 200, and the detailed description is not repeated herein. Different from SAW structure 200, piezoelectric structure 202 may include a plurality of layers, instead of including a single bulk piezoelectric substrate. In some embodiments, piezoelectric structure 202 includes a carrier wafer 203, one or more functional layers (e.g., 1010 and 1012) over a first surface of carrier wafer 203, and a piezoelectric layer 1008 over the functional layers. IDT 1004 may be located on a first surface (e.g., top surface) of piezoelectric layer 1008. Carrier wafer 203 may include any suitable material to provide support to the structures above. In some embodiments, carrier wafer 203 includes silicon, quartz, silicon carbide, sapphire, epoxy, and/or carbon. For example, carrier wafer 203 includes silicon. In some embodiments, functional layer 1010 may be configured for temperature compensation (TC) improvement, and functional layer 1012 may be configured for reduction of parasitic surface conduction (PSC). In some embodiments, functional layer 1012 includes one or more of trap rich layer (or TRL)-silicon, silicon oxide (e.g., silicon dioxide), and/or fluorine-doped silicon oxide (e.g., fluorine-doped silicon dioxide). For example, functional layer 1012 includes TRL-silicon. In some embodiments, functional layer 1010 includes one or more of silicon oxide (e.g., silicon dioxide), fluorine-doped silicon oxide (e.g., fluorine-doped silicon dioxide), and/or quartz. For example, functional layer 1010 includes silicon oxide. Piezoelectric layer 1008 may include one or more of aluminum nitride (AlN), zinc oxide (ZnO), aluminum scandium nitride (AlScN), lithium tantalate (LT), lithium niobate (LN). In some embodiments, piezoelectric layer 1008 includes lithium tantalate (LT).

Embedded acoustic reflectors 1006-1 and 1006-2 may be similar to embedded acoustic reflectors 206-1 and 206-2, respectively. For example, embedded acoustic reflectors 1006-1 and 1006-2 may have similar depth d, width w, angles α1 and α2 to the respective sidewalls, and distance 1 to IDT 1004. In some embodiments, depth d may be equal to or greater than a thickness t of piezoelectric layer 1008 in the z-direction. In some embodiments, the second surface (e.g., bottom surface) of embedded acoustic reflector 1006-1/1006-2 is located between a second surface (e.g., the bottom surface) of piezoelectric layer 1008 and the first surface (e.g., the top surface) of carrier wafer 203. In some embodiments, the second surface of embedded acoustic reflector 1006-1/1006-2 may be coplanar with the first surface of carrier wafer 203, or below the first surface of carrier 203 (e.g., located between the first and second surfaces of carrier wafer 203). In various embodiments, the value of d may vary, dependent on different applications. For example, the value of d may be determined based on the wavelength of the acoustic wave propagated in IDT 1004.

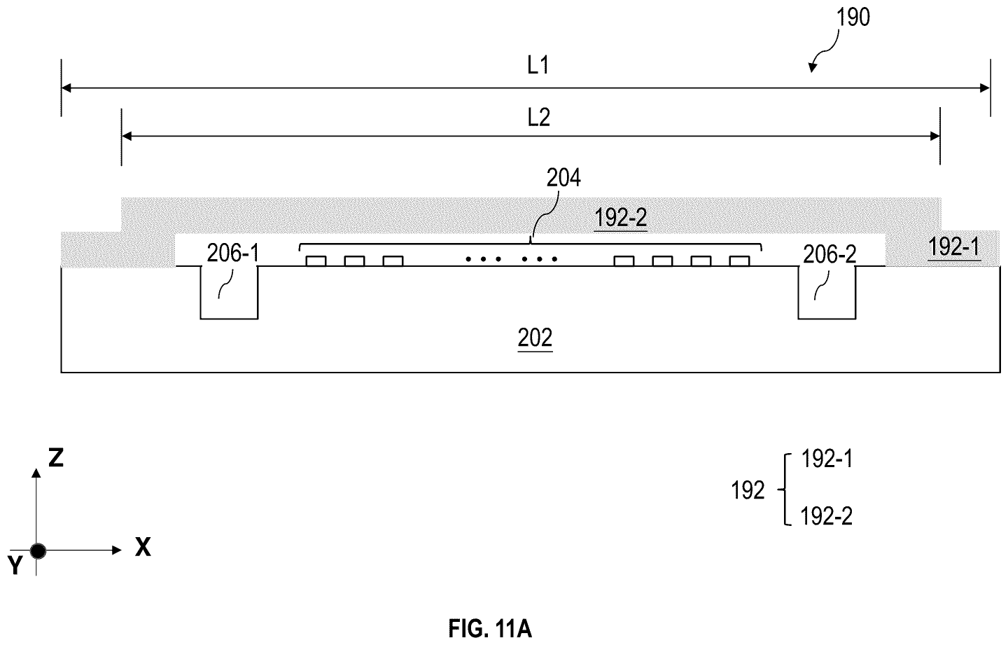

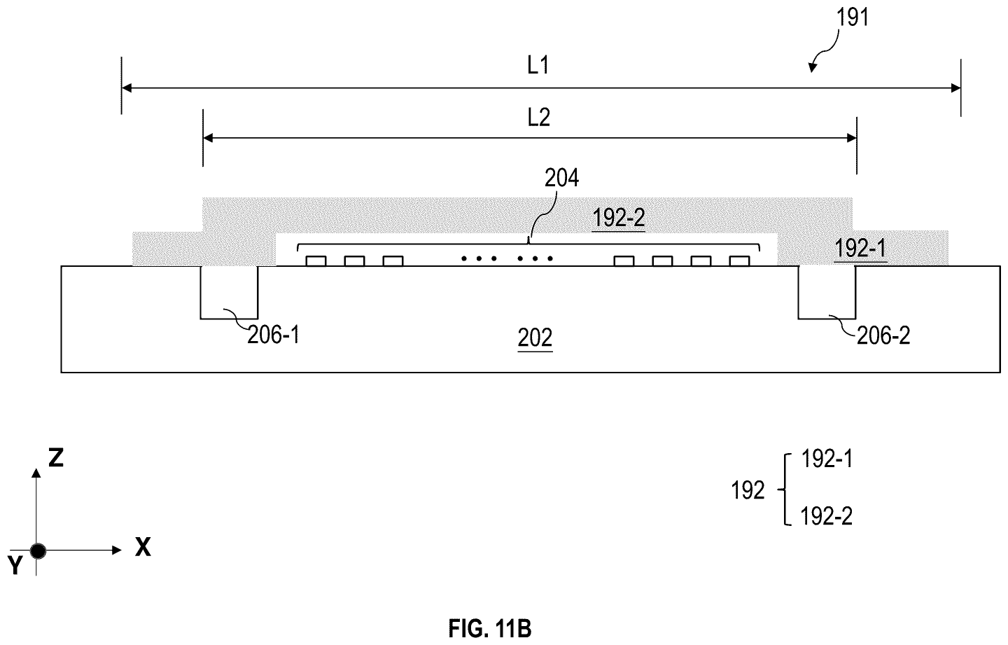

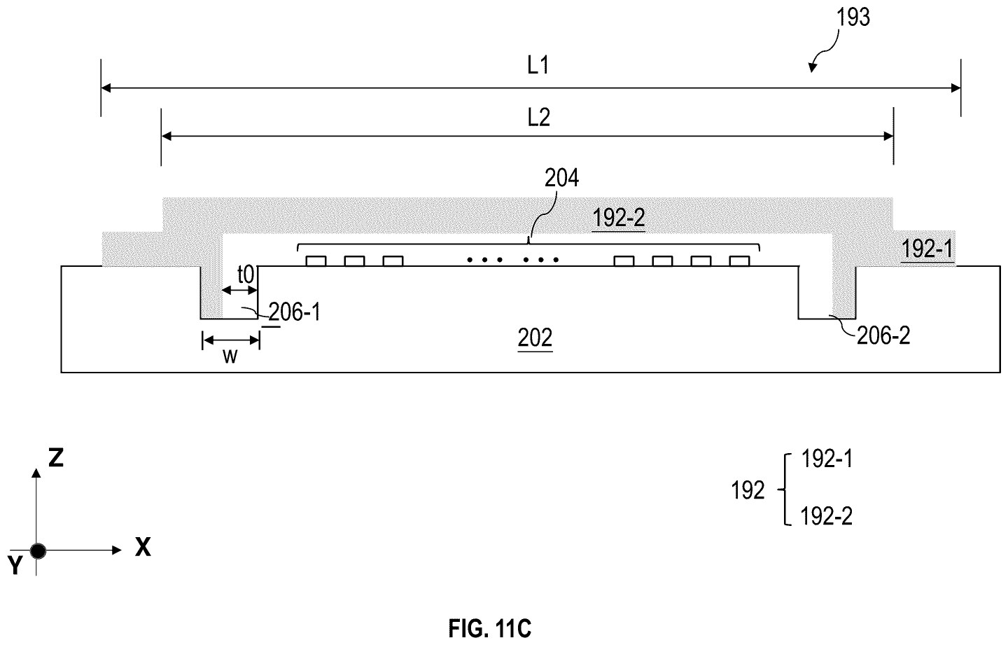

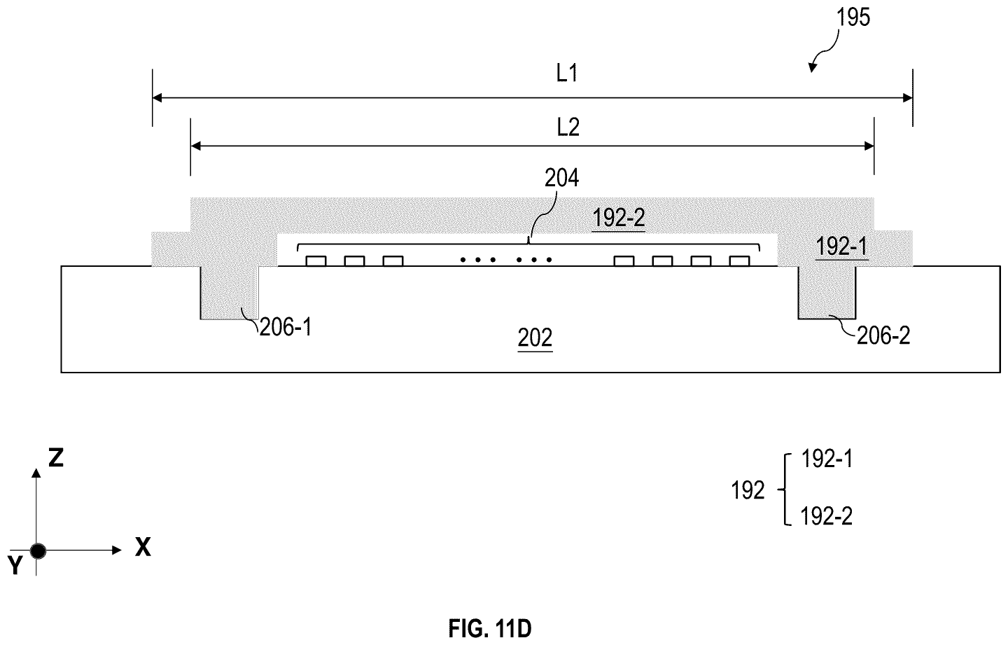

FIGS. 11A-11D illustrate examples of packaged SAW structures 190, 191, 193, and 195 with embedded acoustic reflectors, according to embodiments of the present disclosure. As an example, SAW structure 200 is packaged. A packaging structure 192 (e.g., a wafer-level package) may include a first portion 192-1 in contact with the first surface of piezoelectric structure 202, and a second portion 192-2 in contact with first portion 192-1. Second portion 192-2 may be over IDT 204, and may be separated from IDT 204 with an airgap. In some embodiments, packaging structure 192 may encapsulate at least IDT 204. It should be noted that, any of the SAW structures in this disclosure may be packaged similar to SAW structure 200, e.g., with first portion 192-1 surrounding the outer perimeter of the IDT, and second portion 192-1 over first portion 192-1. As shown in FIGS. 11A-11D, in the x-direction, the first portion of packaging structure 192-1 may have a dimension of L1, and the second portion of packaging structure 192-2 may have a dimension of L2. In some embodiments, L2 is less than L1. In some embodiments, the value of L2 is partially determined by the value of L1. For example, the value of L2 may decrease as the value of L1 decreases.

As shown in FIG. 11A, in packaged SAW structure 190, first portion 192-1 may be away from, e.g., having no contact with, embedded acoustic reflectors 206-1 and 206-2, such that embedded acoustic reflectors 206-1 and 206-2 are fully filled with air (e.g., being airgaps). In some embodiments, packaging structure 192 fully encapsulates IDT 204 and embedded acoustic reflectors 206-1 and 206-2. In some embodiments, L1 is greater than L2, and L2 is greater than or equal to the total length of IDT 204 and embedded acoustic reflectors 206-1 and 206-2.

As shown in FIG. 11B, in packaged SAW structure 191, first portion 192-1 may be over embedded acoustic reflectors 206-1 and 206-2. For example, first portion 192-1 may be in contact with the first surfaces of embedded acoustic reflectors 206-1 and 206-2 such that embedded acoustic reflectors 206-1 and 206-2 are fully filled with air (e.g., being airgaps). First portion 192-1 may cover but not fill embedded acoustic reflectors 206-1 and 206-2. In some embodiments, embedded acoustic reflectors 206-1 and 206-2 may each have a depth d and width w, referring back to FIG. 2. In some embodiments, packaging structure 192 fully encapsulates IDT 204 but not embedded acoustic reflectors 206-1 and 206-2. In some embodiments, L1 is greater than L2, and L2 is greater than or equal to the total length of IDT 204. In some embodiments, L1 and L2 may each be less than their counterpart in packaged SAW structure 190, e.g., because first portion 192-1 takes less area to encapsulate IDT 204 and the dimension L2 of second portion 192-2 may decrease accordingly. Less area may be used to package SAW structure 200.

As shown in FIG. 11C, in packaged SAW structure 193, first portion 192-1 may partially fill embedded acoustic reflectors 206-1 and 206-2 such that embedded acoustic reflectors 206-1 and 206-2 are each partially filled with air. In some embodiments, packaging structure 192 fully encapsulates IDT 204 and partially encapsulates embedded acoustic reflectors 206-1 and 206-2. For example, embedded acoustic reflector 206-1/206-2 may have a width w, and part of w is filled with the packaging material. The part of embedded acoustic reflector 206-1/206-2 not filled with air may have a width of t0 in the x-direction, which is less than w. In some embodiments, L1 and L2 may each be less than their counterpart in packaged SAW structure 190, e.g., because first portion 192-1 takes less area to encapsulate IDT 204 and the dimension L2 of second portion 192-2 may decrease accordingly. Less area may be used to package SAW structure 200.

As shown in FIG. 11D, in packaged SAW structure 195, first portion 192-1 may fully fill embedded acoustic reflectors 206-1 and 206-2 such that embedded acoustic reflectors 206-1 and 206-2 are each fully filled with the packaging material. In some embodiments, packaging structure 192 fully encapsulates IDT 204 but not embedded acoustic reflectors 206-1 and 206-2. In some embodiments, L1 and L2 may each be less than their counterpart in packaged SAW structure 190, e.g., because first portion 192-1 takes less area to encapsulate IDT 204 and the dimension L2 of second portion 192-2 may decrease accordingly. Less area may be used to package SAW structure 200.

In this disclosure, although not specified, the electrode fingers of an IDT may include one or more metals and/or including adhesion and conductive layers. The shapes of the electrode fingers can be arbitrary meaning the sidewall angles can differ from being vertical. In some embodiments, on top of an IDT, other dielectric layers may be added to cover the IDT, e.g., for temperature compensation or passivation. In some embodiments, the electrode fingers may be covered by passivation or temperature compensating layers, e.g. by silicon nitride and/or silicon oxide layers. This passivation may extend into the embedded acoustic reflector area. For example, an embedded acoustic reflector may include a silicon nitride layer and/or a silicon oxide layer covering the sidewalls and/or bottom surface. The embodiments are depicted for one-port resonators with one IDT or two IDTs, but can be applied in the same way also for multi-port structures comprising multiple IDT's between the reflectors like e.g., CRF's, or entire filter topologies using multiple resonators and/or CRF's.

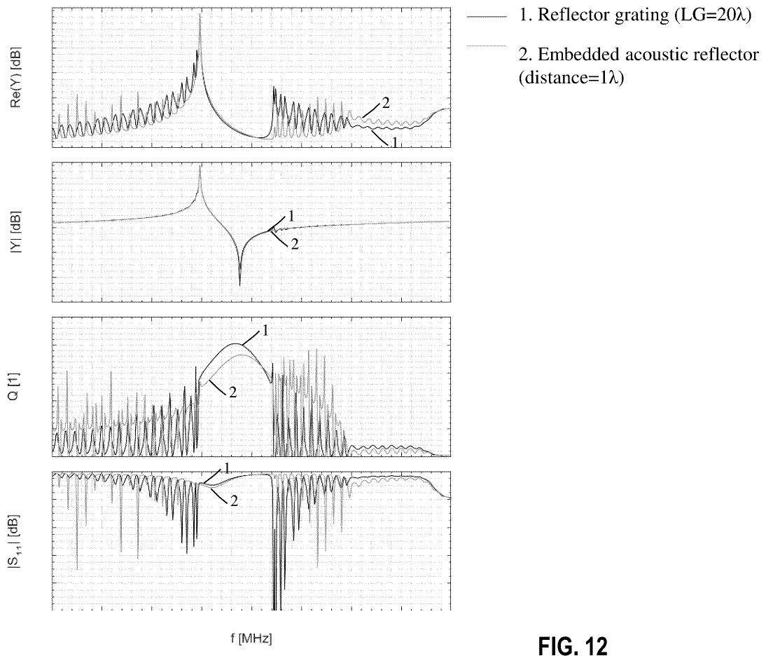

FIG. 12 shows a finite element method (FEM) simulation results of SAW structure 1000 benchmarking the embedded acoustic reflector approach from this disclosure against conventional reflective gratings (RG) structures with a grating length (LG) of 202. For the embedded acoustic reflector case one optimum at a distance of 1λ was selected. Plotted are from top to bottom, the conductance (real part of admittance Re(Y)), the absolute value of the admittance |Y|, the Bode quality factor Q, and the return loss |S₁₁|. In the conductance it can be clearly seen that the stopband widths of the resonator are similar for both cases. Moreover, the stopband is spurious free for the embedded acoustic reflector case at that distance and the losses are comparable to the RG case. In the Q plot it can be seen that Q is slightly lower in the stopband but this can be adjusted by the depth of the embedded acoustic reflector depending on the requirements. The electromechanical coupling (kₑ²) is also not affected and stays the same for both cases. Another potential benefit of the disclosed embedded acoustic reflector over RG may be that the losses at and above the upper stopband edge and below the lower stopband edge are lower, which can also be clearly seen in the Q plot. The longitudinal mode beating below the lower stop band edge (LSBE) and above the upper stop band edge (USBE) is showing narrower and more pronounced peaks which means better wave confinement. Additionally, below resonance frequency (fs at LSBE) the longitudinal mode beating is much reduced for the first couple of modes in the RC case. This can also be a potential benefit for filter designs if this could inherently be achieved without design tricks at the cost of performance tradeoffs.

In various embodiments, the embedded acoustic reflectors are formed after the formation of IDT and any reflective gratings. The IDT, including a plurality of electrode fingers, and any reflective gratings, may be formed in the same process. For example, the formation of IDT and any reflective gratings may include a suitable deposition such as E-beam evaporation, plating, atomic layer deposition (ALD), chemical vapor deposition (CVD), physical vapor deposition (PVD), or a combination thereof. The formation may also include a patterning process that includes a photolithography process and an etching process (e.g., dry etch and/or wet etch).

In some embodiments, the embedded acoustic reflectors are formed by patterning the supporting structure, e.g., bulk piezoelectric substrate and/or multi-layer piezoelectric structure, under the IDT. The patterning of the embedded acoustic reflectors may include a photolithography process, and an etching process (e.g., dry etch and/or wet etch) with an etch mask that covers the IDT and any reflective gratings and exposes the area for forming the embedded acoustic reflectors. In some embodiments, the SAW structure may include one or more dummy electrode structures that are formed in the same patterning process that forms the IDT. The dummy electrodes may not be electrically activated and may be used as an etch mask to form the embedded acoustic reflectors. In some embodiments, the dummy electrodes may not be patterned to have the same dimensions as the electrode fingers in the IDT. For example, the dummy electrodes may be larger/wider or smaller/narrower than the electrode fingers in the x-direction, referring back to the description of SAW structures 800 and 900, and the detailed description is not repeated herein. In various embodiments, the etching profile of the embedded acoustic reflectors are optimized for the desired reflectivity. For example, the depth d, width w, angles α1 and/or α2 of an embedded acoustic reflector, and/or the distance 1 between the embedded acoustic reflector and the IDT may be controlled to reach desired values for desired acoustic reflectivity.

1. A surface acoustic wave (SAW) structure, comprising:
an interdigital transducer (IDT) over a first surface of a piezoelectric structure, the IDT comprises a first electrode finger and a second electrode finger arranged in parallel along a first direction and at least partially overlapped with each other;
a first embedded acoustic reflector in the piezoelectric structure on one side of the IDT along a second direction different from the first direction; and
a second embedded acoustic reflector in the piezoelectric structure on another side of the IDT along the second direction, wherein:
a first surface of each of the first embedded acoustic reflector and the second embedded acoustic reflector is coplanar with the first surface of the piezoelectric structure; and
a second surface of each of the first embedded acoustic reflector and the second embedded acoustic reflector is located between the first surface and a second surface of the piezoelectric structure.

2. The SAW structure of claim 1, wherein the first embedded acoustic reflector and the second embedded acoustic reflector each comprises an airgap.

3. The SAW structure of claim 1, wherein:
a first distance between each of the first embedded acoustic reflector and the second embedded acoustic reflector, and a closest one of the first electrode finger and the second electrode finger is between about 0 and about 15λ, λ being a wavelength of an acoustic wave propagating in the IDT;
a second distance between the first surface and the second surface of each of the first embedded acoustic reflector and the second embedded acoustic reflector is between about 0.25 μm and about 5λ;
a first side surface of each of the first embedded acoustic reflector and the second embedded acoustic reflector closer to the IDT and a second side surface of each of the first embedded acoustic reflector and the second embedded acoustic reflector further from the IDT is at least 0.1 μm; and
an angle between a side surface and the second surface is between about 80 degrees and about 135 degrees.

4. The SAW structure of claim 1, further comprising:
a first reflective grating over the piezoelectric structure and between the IDT and the first embedded acoustic reflector; and
a second reflective grating over the piezoelectric structure and between the IDT and the second embedded acoustic reflector.

5. The SAW structure of claim 1, further comprising:
a second IDT over the piezoelectric structure apart from the IDT along the second direction; and
a third embedded acoustic reflector in the piezoelectric structure between the second embedded acoustic reflector and the second IDT.

6. The SAW structure of claim 5, wherein a distance between the second embedded acoustic reflector and the third embedded acoustic reflector is between about 0.1 μm and about 2×15λ, λ being a wavelength of an acoustic wave propagating in the IDT.

7. The SAW structure of claim 1, further comprising a second IDT over the piezoelectric structure apart from the IDT along the second direction,
wherein the second IDT is immediately adjacent to the second embedded acoustic reflector.

8. The SAW structure of claim 4, further comprising:
a second IDT over the piezoelectric structure apart from the IDT along the second direction;
a third embedded acoustic reflector in the piezoelectric structure and adjacent to the second embedded acoustic reflector; and
a third reflective grating over the piezoelectric structure and between the second IDT and the third embedded acoustic reflector.

9. The SAW structure of claim 8, wherein a distance between the second embedded acoustic reflector and the third embedded acoustic reflector is between about 0.1 μm and about 2×15λ, λ being a wavelength of an acoustic wave propagating in the IDT.

10. The SAW structure of claim 4, further comprising:
a second IDT over the piezoelectric structure apart from the IDT along the second direction; and
a third reflective grating over the piezoelectric structure and between the second IDT and the second embedded acoustic reflector.

11. The SAW structure of claim 1, wherein the piezoelectric structure comprises:
a carrier substrate;
a functional layer over the carrier substrate; and
a piezoelectric layer over the functional layer.

12. The SAW structure of claim 11, wherein a distance between the first surface and the second surface of each of the first embedded acoustic reflector and the second embedded acoustic reflector is equal to or greater than a thickness of the piezoelectric layer.

13. The SAW structure of claim 12, wherein the second surface of each of the first embedded acoustic reflector and the second embedded acoustic reflector is in contact with the carrier substrate.

14. The SAW structure of claim 1, wherein the piezoelectric structure comprises a bulk piezoelectric substrate.

15. The SAW structure of claim 1, further comprises:
a first dummy electrode structure located between the IDT and the first embedded acoustic reflector in the second direction; and
a second dummy electrode structure located between the IDT and the second embedded acoustic reflector in the second direction, wherein:
a distance between the first embedded acoustic reflector and the first dummy electrode structure is zero such that an edge of the first dummy electrode structure aligns with a side surface of the first embedded acoustic reflector; and
a distance between the second embedded acoustic reflector and the second dummy electrode structure is zero such that an edge of the second dummy electrode structure aligns with a side surface of the second embedded acoustic reflector.

16. The SAW structure of claim 15, wherein along the second direction, a dimension of the first dummy electrode structure or the second dummy electrode structure is equal to, less than, or greater than a dimension of the first electrode finger or the second electrode finger.

17. The SAW structure of claim 15, further comprising:
a first reflective grating located between the first dummy electrode structure and the IDT; and
a second reflective grating located between the second dummy electrode structure and the IDT.

18. The SAW structure of claim 1, further comprising a packaging structure covering the IDT, the first embedded acoustic reflector, and the second embedded acoustic reflector, wherein the packaging structure comprises:
a first portion in contact with the piezoelectric structure; and
a second portion in contact with the first portion.

19. The SAW structure of claim 17, wherein the first portion of the packaging structure is located apart from the IDT, the first embedded acoustic reflector, and the second embedded acoustic reflector such that the second portion of the packaging structure is separated from the IDT, the first embedded acoustic reflector, and the second embedded acoustic reflector by another airgap.

20. The SAW structure of claim 17, wherein the first portion of the packaging structure is located apart from the IDT, and over the first embedded acoustic reflector and the second embedded acoustic reflector such that the second portion of the packaging structure is separated from the IDT by another airgap.
